(19) United States
(12) Patent Application Publication
(10) Pub. No.: US 2025/0365992 A1
(43) Pub. Date: Nov. 27, 2025

(54) SEMICONDUCTOR DEVICE INCLUDING OXIDE FILM AND STRUCTURE, AND METHOD OF MANUFACTURING SAME

(71) Applicant: DB HiTek Co., Ltd., Bucheon-si (KR)

(72) Inventors: Nam Kyu KIM, Eumseong-gun (KR); Su Hwan LIM, Eumseong-gun (KR); Seung Hyun LIM, Eumseong-gun (KR)

(21) Appl. No.: 18/769,619

(22) Filed: Jul. 11, 2024

(30) Foreign Application Priority Data
May 27, 2024 (KR) 10-2024-0068287

(51) Int. Cl. H01L 21/02; H01L 21/3105; H01L 21/762

(52) U.S. Cl. CPC H10D 1/47; H01L 21/0223; H01L 21/31053; H01L 21/76224

(57) ABSTRACT

A semiconductor device including an oxide film and a structure, and a method of manufacturing the same enable a first surface and/or a second surface of a second oxide film to have a convex shape so that the second oxide film formed has a larger thickness, thus preventing breakdown voltage characteristics between a substrate and the structure from deteriorating.

### CROSS REFERENCE TO RELATED APPLICATION

The present application claims priority to Korean Patent Application No. 10-2024-0068287, filed May 27, 2024, the entire contents of which is incorporated herein for all purposes by this reference.

### BACKGROUND OF THE INVENTION

### Field of the Invention

The present disclosure relates to a semiconductor device including an oxide film and a structure, and to a method of manufacturing the same. More specifically, the present disclosure relates to a semiconductor device including an oxide film and a structure, and to a method of manufacturing the same, enabling a first surface and/or a second surface of a second oxide film to have a convex shape so that the second oxide film formed has a larger thickness, thus preventing breakdown voltage characteristics between a substrate and the structure from deteriorating.

### Description of the Related Art

An analog circuit of a semiconductor device is constructed using devices such as a resistor. Typically, when forming a resistor on a semiconductor substrate, a device isolation film is formed using a shallow trench isolation (STI) process to minimize noise caused by interaction between the resistor and a silicon substrate serving as the semiconductor substrate. However, during such an STI process, limitations in uniformity due to a chemical mechanical polishing (CMP) process may lead to deterioration in breakdown voltage characteristics between the substrate and the resistor.

FIG. 1 is a cross-sectional diagram illustrating an existing polysilicon resistor structure. Referring to FIG. 1, when performing a CMP process on the surface of a gap-filled oxide film 911 in a trench formed in a substrate 901, dishing D occurs on the surface of the oxide film 911. In addition, cracks C may occur in the oxide film 911 due to the stress applied to the oxide film 911. As described above, when the oxide film 911 involves such dishing D or cracks C, the vertical thickness of the oxide film 911 becomes relatively small, leading to deterioration in breakdown voltage characteristics between the substrate 901 and a resistor 920. In particular, with advanced chip design, the working voltage level between the substrate 901 and the resistor 920 must be improved when requiring a high voltage level between the two, but there are limitations.

To solve such a problem, the inventors of the present disclosure have proposed a semiconductor device including a novel oxide film and a structure, and a method of manufacturing the same, which will be described in detail later.

### DOCUMENTS OF RELATED ART

### Patent Document

Korean Patent Application Publication No. 10-2006-0079319 “METHOD OF FORMING SHALLOW TRENCH ISOLATION (STI)-TYPE DEVICE ISOLATION FILM OF SEMICONDUCTOR DEVICE”

### SUMMARY OF THE INVENTION

The present disclosure, which has been proposed to solve the above-described problems in the related art, aims to provide a semiconductor device including an oxide film and a structure, and a method of manufacturing the same, enabling the regrowth of a first oxide film for forming a shallow trench isolation (STI) region to remove cracks existing in the first oxide film and/or reduce the level of dishing and thus preventing breakdown voltage characteristics between a substrate and a structure from deteriorating.

In addition, the present disclosure aims to provide a semiconductor device including an oxide film and a structure, and a method of manufacturing the same, enabling a second oxide film having a relatively large thickness to be easily formed by performing a wet oxidation process during the regrowth of a first oxide film.

In addition, the present disclosure aims to provide a semiconductor device including an oxide film and a structure, and a method of manufacturing the same, inducing a first oxide film to regrow together when performing a local oxidation of silicon (LOCOS) process for forming the semiconductor device and thus eliminating the need for a separate additional process for forming a second oxide film.

The present disclosure may be implemented by embodiments having the following configuration to achieve the above-described objectives.

According to a first embodiment of the present disclosure, a semiconductor device is characterized by including a substrate including a trench, an oxide film serving as a device isolation film in the trench, and a structure disposed on the oxide film and having a lower surface facing an upper surface of the oxide film, wherein the oxide film has a first surface having a convex shape.

According to a second embodiment of the present disclosure, the semiconductor device may be characterized in that the oxide film has a second surface being opposite to the first surface and having a convex shape.

According to a third embodiment of the present disclosure, the semiconductor device may be characterized in that the oxide film has a second surface being opposite to the first surface and having a concave shape.

According to a fourth embodiment of the present disclosure, the semiconductor device may be characterized in that the oxide film is formed by filling the trench with a first oxide film and then regrowing the first oxide film.

According to a fifth embodiment of the present disclosure, the semiconductor device may be characterized in that the structure is a polysilicon film.

According to a sixth embodiment of the present disclosure, a method of manufacturing a semiconductor device including an oxide film and a structure is characterized by including the following steps: forming a trench in a substrate, forming an oxide film in the trench and on the substrate, forming a device isolation film made of a first oxide film in the trench by performing a chemical mechanical polishing (CMP) process on the oxide film, forming a second oxide film by regrowing the first oxide film through a thermal oxidation process performed on the first oxide film and, and forming a structure on the second oxide film.

According to a seventh embodiment of the present disclosure, the method may be characterized in that the minimum vertical thickness of the second oxide film is larger than that of the first oxide film.

According to an eighth embodiment of the present disclosure, the method may be characterized in that the second oxide film is formed through a wet oxidation process.

According to a ninth embodiment of the present disclosure, the method may be characterized in that the step of forming the second oxide film includes the following steps: forming a pad oxide film on the substrate, forming a nitride film on the pad oxide film, etching the nitride film and the pad oxide film so that the first oxide film is exposed, and regrowing the first oxide film through the thermal oxidation process.

According to a tenth embodiment of the present disclosure, the method may be characterized in that the second oxide film is formed through a local oxidation of silicon (LOCOS) process.

According to an eleventh embodiment of the present disclosure, the method may be characterized in that the step of forming the structure includes the following steps: forming a polysilicon film on the substrate and the second oxide film, and forming a polysilicon resistor on the second oxide film by etching the polysilicon film.

According to a twelfth embodiment of the present disclosure, the method may be characterized in that the second oxide film has a lower surface having a curved shape.

According to a thirteenth embodiment of the present disclosure, the method may be characterized in that the oxide film has an upper surface having a convex shape.

According to a fourteenth embodiment of the present disclosure, a method of manufacturing a semiconductor device including an oxide film and a structure is characterized by including the following steps: forming a trench in a substrate, forming an oxide film in the trench and on the substrate, forming a device isolation film made of a first oxide film in the trench by performing a CMP process on the oxide film, forming a second oxide film by regrowing the first oxide film, and forming a polysilicon resistor on the second oxide film, wherein dishing occurs on a surface of the first oxide film.

According to a fifteenth embodiment of the present disclosure, the method may be characterized in that the first oxide film has a lower surface that is substantially planar.

According to a sixteenth embodiment of the present disclosure, the method may be characterized in that the second oxide film has a lower surface that is downwardly convex.

According to a seventeenth embodiment of the present disclosure, the method may be characterized in that the second oxide film has a greater surface curvature than the first oxide film.

According to an eighteenth embodiment of the present disclosure, the method may be characterized in that the second oxide film is formed by regrowing the first oxide film through a thermal oxidation process performed on the first oxide film.

According to a nineteenth embodiment of the present disclosure, the method may be characterized in that the second oxide film is formed through a wet oxidation process.

The present disclosure has the following effects based on the above-described configuration.

The present disclosure enables the regrowth of a first oxide film for forming a shallow trench isolation (STI) region to remove cracks existing in the first oxide film and/or reduce the level of dishing, thus preventing breakdown voltage characteristics between a substrate and a structure from deteriorating.

In addition, the present disclosure enables a second oxide film having a relatively large thickness to be easily formed by performing a wet oxidation process during the regrowth of the first oxide film.

In addition, the present disclosure induces the first oxide film to regrow together when performing a local oxidation of silicon (LOCOS) process for forming a semiconductor device, thus eliminating the need for a separate additional process for forming the second oxide film.

On the other hand, it is further stated that even when not explicitly mentioned herein, the effects herein expected by the technical features of the present disclosure and potential effects thereof are treated as those described herein of the present disclosure.

### BRIEF DESCRIPTION OF THE DRAWINGS

FIG. 1 is a cross-sectional diagram illustrating an existing polysilicon resistor structure;

FIG. 2 is a cross-sectional diagram illustrating a semiconductor device including an oxide film and a structure, according to one embodiment of the present disclosure;

FIGS. 3 to 12 are cross-sectional diagrams illustrating a method of manufacturing a semiconductor device including an oxide film and a structure, according to one embodiment of the present disclosure;

FIG. 13 is a graph showing an increase in thickness of a second oxide film when applying a semiconductor device including an oxide film and a structure, and a method of manufacturing the same, according to one embodiment of the present disclosure; and

FIG. 14 is a graph showing improvement in breakdown voltage characteristics between a substrate and a resistor when applying a semiconductor device including an oxide film and a structure, and a method of manufacturing the same, according to one embodiment of the present disclosure.

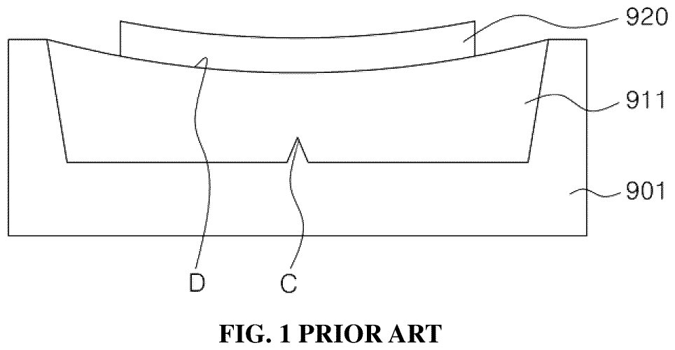

### DETAILED DESCRIPTION OF THE INVENTION

Hereinafter, embodiments of the present disclosure will be described in more detail with reference to the attached drawings. Embodiments of the present disclosure may be modified into various forms. In addition, the scope of the present disclosure should not be construed as being limited to the following embodiments but should be construed on the basis of the appended claims. In addition, the embodiments of the present disclosure described below are provided for allowing those skilled in the art to more clearly comprehend the present disclosure.

It should be noted that when one component (or layer) below is described as being disposed on another component (or layer), one component may be disposed directly on another component, or another component (or components) or layer (or layers) may be disposed between the components. In addition, when one component is expressed as being directly disposed on or above another component, no other component (components) are disposed between the components. In addition, being positioned on the “upper”, “upper portion”, “lower portion”, “upper side”, “lower side”, “one (first) side”, or “side surface” of a component means a relative positional relationship.

It should also be noted that when certain embodiments are implementable otherwise, certain processes may be performed in a sequence different from that described below. For example, two processes described sequentially may be practically performed simultaneously or inversely.

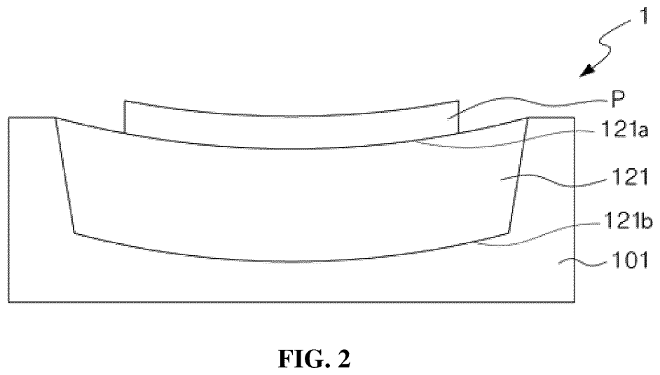

FIG. 2 is a cross-sectional diagram illustrating a semiconductor device including an oxide film and a structure, according to one embodiment of the present disclosure.

Hereinafter, the semiconductor device including the oxide film and the structure, according to one embodiment of the present disclosure, will be described in detail with reference to the attached drawings. The term “structure” used herein may, for example, be a polysilicon film, a metal film, or a film or layer. Although the scope of the present disclosure is not limited by specific examples, the description below will be limited, for convenience, to the case where the structure is a polysilicon film.

In the case where the structure is a polysilicon film, the structure, according to the present disclosure, may be usable as a resistor in the semiconductor device, but the scope of the present disclosure is not limited thereto.

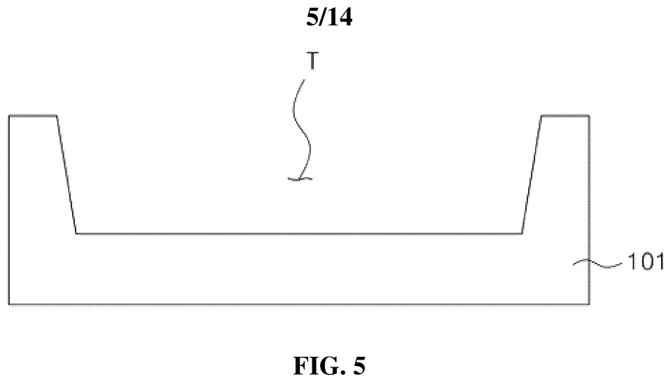

Referring to FIG. 2, a substrate 101 may be formed in the semiconductor device 1 including the oxide film and the structure, according to one embodiment of the present disclosure. In addition, a trench T is formed from the surface of the substrate 101 down to a predetermined depth (see FIG. 5), and the inside of the trench T may be gap-filled with an oxide film 121. In this case, each cross section of the upper surface 121A and/or the lower surface 121B of the oxide film 121 is preferably formed to have a curved shape, which is more preferably formed to have a convex shape. The expression “formed to have a convex shape” above is understood to mean that the oxide film 121 has an upper surface 121A and/or a lower surface 121B having a convex shape in a direction away from the center height of the oxide film 121. In other words, despite being formed to be concave in FIG. 2, the oxide film 121 may have an upper surface 121A that is convex in some cases. In one embodiment of the present disclosure, the oxide film 121 preferably has an upper surface 121A and a lower surface 121B that are concave and convex, respectively, but it should be noted that the scope of the present disclosure is not limited thereto. Hereinafter, the oxide film 121 may, for example, also be referred to as a “second oxide film”, an oxide film from which a first oxide film 111 is regrown. In addition, a “first surface” of the oxide film or second oxide film 121 may be the upper surface 121A or the lower surface 121B, and a second surface may be opposite to the first surface.

In addition, the structure such as the polysilicon film P may be formed on the upper surface 121A of the oxide film 121. The polysilicon film P may be formed in such a shape that the lower surface thereof faces the upper surface 121A of the oxide film 121, or the upper surface thereof faces the upper surface 121A of the oxide film 121, but the scope of the present disclosure is not limited thereto.

Hereinafter, a method of manufacturing the semiconductor device including the oxide film and the structure, according to one embodiment of the present disclosure, will be described in detail with reference to the attached drawings.

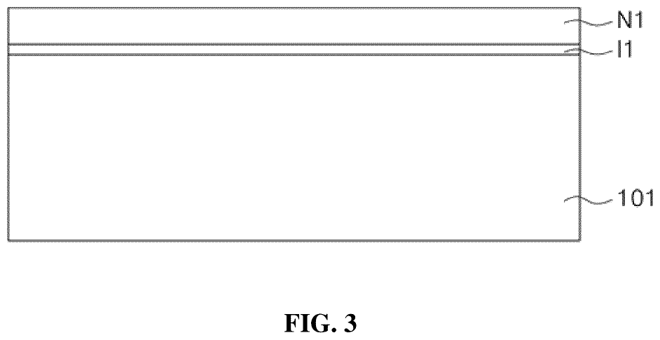

FIGS. 3 to 12 are cross-sectional diagrams to illustrate the method of manufacturing the semiconductor device including the oxide film and the structure, according to one embodiment of the present disclosure.

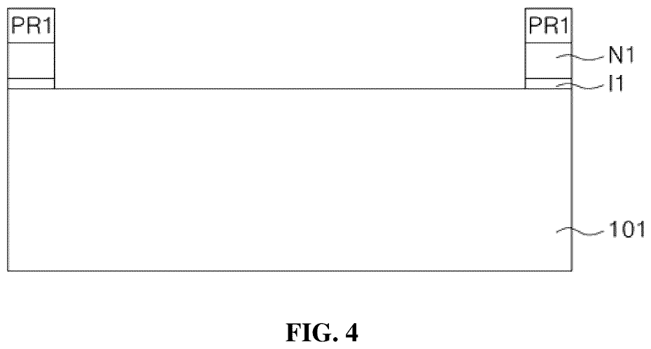

The method of manufacturing the semiconductor device including the oxide film and the structure, according to one embodiment of the present disclosure, is to be described in detail. First, the trench T is formed in the substrate 101. Hereinafter, a method of forming the trench is to be illustratively described. Referring to FIG. 3, a pad oxide film I1 is first formed on the substrate 101. Such a pad oxide film I1 may be formed by performing a wet oxidation process. Then, a pad nitride film N1 used as a hard mask is formed on the pad oxide film I1. Next, referring to FIG. 4, a pattern is formed on the pad nitride film N1 and the pad oxide film I1 by forming a photoresist film PR1 on the pad nitride film N1 and then etching the exposed side of the photoresist film PR1. Thereafter, referring to FIG. 5, the trench T may be formed by etching the substrate 101 using the pad nitride film N1 as the hard mask. Then, the pad oxide film I1 and the pad nitride film N1 are removed. However, the method of forming the trench T in the present disclosure is not limited to the above-described example.

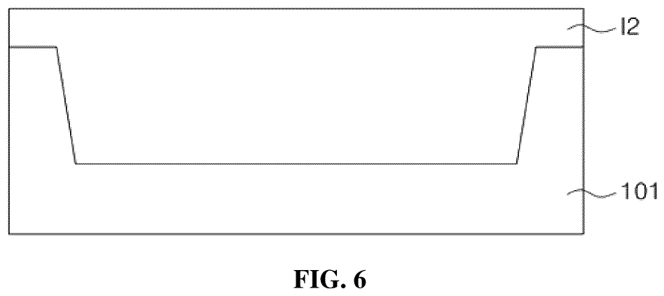

Next, referring to FIG. 6, the trench T is gap-filled with an oxide film 12. In this case, the oxide film 12 is deposited on the substrate 101.

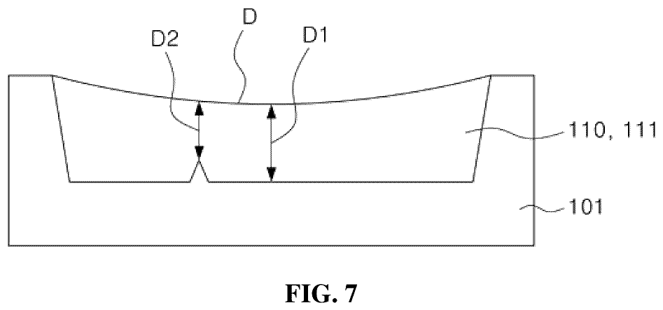

Then, referring to FIG. 7, the oxide film 12 on the substrate 101 is removed by performing a chemical mechanical polishing (CMP) process, thereby completing the formation of a device isolation film 110. When forming the device isolation film 110, the first oxide film 111 may have a lower surface that is substantially planar. In addition, when performing the above-described CMP process, dishing D, which is a deep downward groove, may occur on the surface of the first oxide film 111 of the device isolation film 110. The larger the pattern area of the device isolation film 110, the more noticeably such dishing D occurs.

When the dishing D occurs on the first oxide film 111, the vertical thicknesses D1 of the first oxide film 111 become inevitably smaller. In addition, when cracks C and the like additionally occur in the first oxide film 111 due to the stress concentration on the oxide film 111, the vertical thickness D2 of the first oxide film 111 may become much smaller. This may lead to deterioration in breakdown voltage characteristics between the substrate 101 and a resistor P, which will be described later. In particular, with advanced chip design, there are many cases where a high voltage level between the substrate 101 and the resistor P is required. To this end, the working voltage level between the substrate 101 and the resistor P is required to be improved, but limitations are bound to follow due to the above-described problems.

Thus, one embodiment of the present disclosure is characterized by additionally involving the following processes.

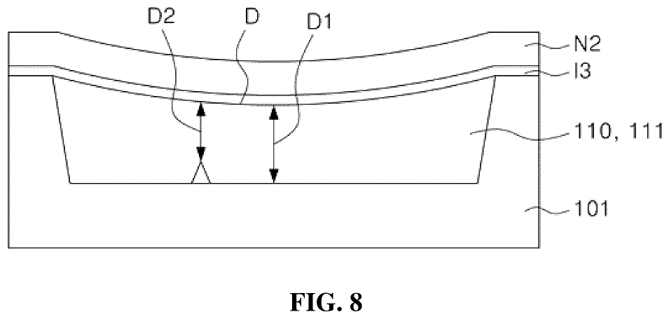

According to one embodiment of the present disclosure, after forming the device isolation film 110, a local oxidation of silicon (LOCOS) process is performed on the first oxide film 111. Hereinafter, the LOCOS process is to be described in detail. Referring to FIG. 8, a pad oxide film I3 is first formed on the substrate 101, followed by forming a nitride film N2 on the pad oxide film I3. The pad oxide film I3 is configured to perform a role as an intermediate buffer because a difference in thermal expansion coefficient between the nitride film N2 and the substrate 101 is large. The nitride film N2 may be made of Si₃N₄ and the like.

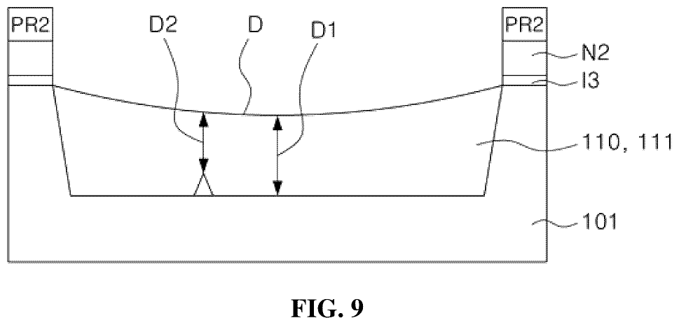

Then, referring to FIG. 9, a photoresist film PR2 on the nitride film N2 is used as a mask pattern to etch the nitride film N2 and the oxide film I3. In other words, the nitride film N2 and the pad oxide film I3 are etched to form a pattern in which the first oxide film 111 is exposed.

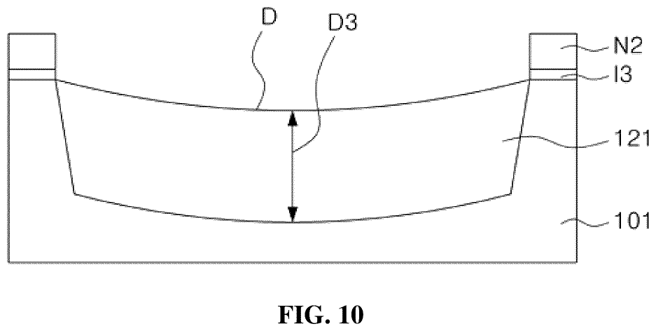

Next, referring to FIG. 10, the first oxide film 111 of the device isolation film 110 is regrown through a thermal oxidation process to form a second oxide film 121. In this case, the cracks C existing in the first oxide film 111 may be removed through the regrowth of the first oxide film 111. In addition, the level of the dishing D on the surface of the second oxide film 121 may be reduced compared to that of the existing first oxide film 111. Thus, the vertical thickness D3 of the second oxide film 121 may be larger than that of the first oxide film 111. Thereafter, the nitride film N2 is removed, and the pad oxide film I3 left on the substrate 101 may be removed in any subsequent process.

In this case, the thermal oxidation process is preferably a wet oxidation process. In other words, when performing the wet oxidation process, the second oxide film 121 may be formed to have a relatively larger thickness compared to when performing a dry oxidation process. Thus, the wet oxidation process is preferably used in the present disclosure. In addition, when forming a gate field plate (not illustrated) on the lower side of a gate electrode of the semiconductor device through the LOCOS process, a separate additional mask or process is unnecessary to form the second oxide film 121 according to one embodiment of the present disclosure.

In addition, the second oxide film 121 may have a lower surface 121B that is downwardly convex, but the scope of the present disclosure is not limited thereto. Furthermore, the upper surface 121A of the second oxide film 121 may have a greater curvature than the surface (or upper surface) of the first oxide film 111.

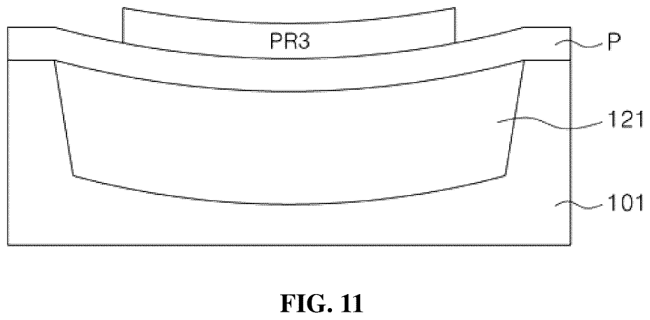

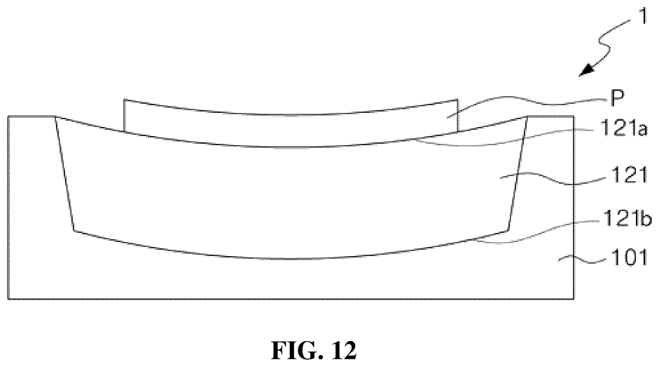

Thereafter, the structure, for example, a polysilicon resistor P, may be formed on the second oxide film 121. Hereinafter, a method of forming the polysilicon resistor is to be illustratively described. Referring to FIG. 11, the polysilicon film P is formed on the substrate 101 and the second oxide film 121. Next, referring to FIG. 12, the polysilicon film P is etched through a photoresist film PR3 disposed thereon, thereby completing the formation of the polysilicon resistor P.

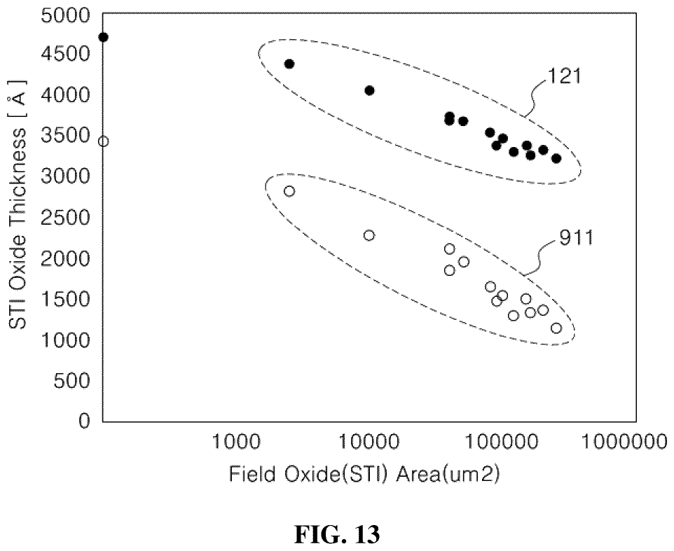

FIG. 13 is a graph showing an increase in thickness of the second oxide film when applying the semiconductor device including the oxide film and the structure, and the method of manufacturing the same, according to one embodiment of the present disclosure.

Referring to FIG. 13, when forming the second oxide film 121 by performing the wet oxidation process on the first oxide film 111 of the device isolation film 110, it is confirmed that the thickness of the oxide film increases by about 1,800 Å compared to that of the existing oxide film 911. Accordingly, breakdown voltage characteristics between the substrate 101 and the resistor P are enabled to be improved compared to that in the related art.

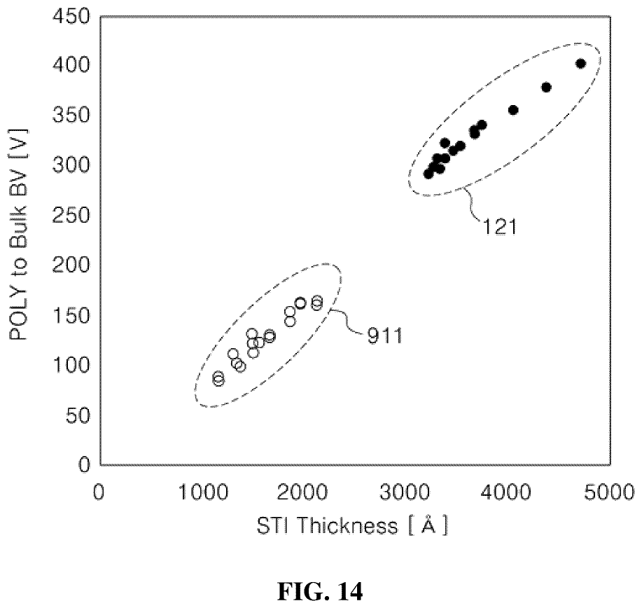

FIG. 14 is a graph showing improvement in breakdown voltage characteristics between the substrate and the resistor when applying the semiconductor device including the oxide film and the structure, and the method of manufacturing the same, according to one embodiment of the present disclosure.

In addition, referring to FIG. 14, when forming the second oxide film 121 by performing the wet oxidation process on the first oxide film 111 of the device isolation film 110, it is confirmed that the breakdown voltage level between the substrate 101 and the resistor P increases by about 200 V compared to that in the existing structure.

The above-detailed description is illustrative of the present disclosure. In addition, the above description shows and describes preferred embodiments of the present disclosure, and the present disclosure can be used in various other combinations, modifications, and environments. In other words, changes or modifications are possible within the scope of the concept of the disclosure disclosed herein, the scope equivalent to the written disclosure, and/or the scope of skill or knowledge in the art. The above-described embodiments describe the best state for implementing the technical idea of the present disclosure, and various changes required in the specific application field and use of the present disclosure are possible. Accordingly, the detailed description of the present disclosure is not intended to limit the present disclosure to the disclosed embodiments.

What is claimed is:

1. A semiconductor device comprising:
a substrate comprising a trench;
an oxide film configured to serve as a device isolation film, the oxide film being disposed in the trench; and
a structure disposed on the oxide film and having a lower surface facing an upper surface of the oxide film,
wherein the oxide film has a first surface having a convex shape.

2. The semiconductor device of claim 1, wherein the oxide film has a second surface defined opposite to the first surface and having a convex shape.

3. The semiconductor device of claim 1, wherein the oxide film has a second surface defined opposite to the first surface and having a concave shape.

4. The semiconductor device of claim 1, wherein the oxide film is formed by filling the trench with a first oxide film and then regrowing the first oxide film.

5. The semiconductor device of claim 1, wherein the structure has a polysilicon film.

6. A method of manufacturing a semiconductor device, the method comprising:
forming a trench in a substrate;
forming an oxide film in the trench and on the substrate;
forming a device isolation film having a first oxide film in the trench by performing a chemical mechanical polishing (CMP) process on the oxide film;
forming a second oxide film by regrowing the first oxide film through a thermal oxidation process performed on the first oxide film; and
forming a structure on the second oxide film.

7. The method of claim 6, wherein a minimum vertical thickness of the second oxide film is larger than a minimum vertical thickness of the first oxide film.

8. The method of claim 6, wherein the thermal oxidation process includes a wet oxidation process.

9. The method of claim 6, wherein the forming of the second oxide film comprises:
forming a pad oxide film on the substrate;
forming a nitride film on the pad oxide film;
etching the nitride film and the pad oxide film so that the first oxide film is exposed; and
regrowing the first oxide film through the thermal oxidation process.

10. The method of claim 6, wherein the second oxide film is formed through a local oxidation of silicon (LOCOS) process.

11. The method of claim 6, wherein the forming of the structure comprises:
forming a polysilicon film on the substrate and the second oxide film; and
forming a polysilicon resistor on the second oxide film by etching the polysilicon film.

12. The method of claim 6, wherein the second oxide film has a lower surface having a curved shape.

13. The method of claim 12, wherein the second oxide film has an upper surface having a convex shape.

14. A method of manufacturing a semiconductor device, the method comprising:
forming a trench in a substrate;
forming an oxide film in the trench and on the substrate;
forming a device isolation film having a first oxide film in the trench by performing a CMP process on the oxide film;
forming a second oxide film by regrowing the first oxide film; and
forming a polysilicon resistor on the second oxide film,
wherein dishing occurs on a surface of the first oxide film.

15. The method of claim 14, wherein the first oxide film has a lower surface that is substantially planar.

16. The method of claim 15, wherein the second oxide film has a lower surface that is downwardly convex.

17. The method of claim 14, wherein the second oxide film has a greater surface curvature than a surface curvature of the first oxide film.

18. The method of claim 14, wherein the second oxide film is formed by regrowing the first oxide film through a thermal oxidation process performed on the first oxide film.

19. The method of claim 18, wherein the thermal oxidation process includes a wet oxidation process.
